(19) United States
(12) Patent Application Publication
(10) Pub. No.: US 2013/0235529 A1
(43) Pub. Date: Sep. 12, 2013

(54) HEAT CONDUCTING DEVICE AND ELECTRONIC DEVICE APPLYING THE SAME

(71) Applicant: HUAWEI TECHNOLOGIES CO., LTD., Shenzhen (CN)

(72) Inventors: Youquan YANG, Shenzhen (CN); Shuzhong LIU, Shenzhen (CN); Haixia WEI, Shenzhen (CN); Bo YANG, Shenzhen (CN)

(73) Assignee: Huawei Technologies Co., Ltd., Shenzhen (CN)

(21) Appl. No.: 13/871,584

(22) Filed: Apr. 26, 2013

Related U.S. Application Data
(63) Continuation of application No. PCT/CN2011/074077, filed on May 16, 2011.

(30) Foreign Application Priority Data
Nov. 11, 2010 (CN) 201010539924.0

(51) Int. Cl. F28F 13/00; H05K 7/20

(52) U.S. Cl. CPC F28F 13/00; H05K 7/2039
USPC 361/704; 165/96

(57) ABSTRACT

A heat conducting device, comprising a first heat conducting board and a heat conducting structure, the first heat conducting board comprising an upper heat conducting arm provided on one surface of the first heat conducting board, the heat conducting structure slidably abutting against the upper heat conducting arm of the first heat conducting board to form a contact surface through which heat transfer is realized, the heat conducting structure comprising a heat conducting surface, wherein the heat conducting structure is used to keep the relative position between the first heat conducting board and the heat conducting surface, allow the varying of the distance between the first heat conducting board and the heat conducting surface of the heat conducting structure through relative sliding between the upper heat conducting arm and the heat conducting structure.

### CROSS-REFERENCE TO RELATED APPLICATIONS

This application is a continuation of International Patent Application No. PCT/CN2011/074077, filed on May 16, 2011, which claims priority to Chinese Patent Application No. 201010539924.0, filed on Nov. 11, 2010, both of which are hereby incorporated by reference in their entireties.

### TECHNICAL FIELD

The present invention relates to a heat conducting device, and more specifically, to a heat conducting device applicable in electronic devices.

### DESCRIPTION OF THE RELATED ART

In current electronic devices, with the continuous abundant of functions, corresponding power consumption is constantly increasing, as a result, heat dispersion of electronic devices has become an important issue restricting the development of electronic devices. In order to enable heat produced in an electronic product to transfer to a heat dispersion device in time, a heat conducting medium is generally provided between the heat source of the electronic product and the heat dispersion device, so that heat produced from the heat source of the electronic product may be conducted to the heat dispersion device.

In the implementation of this invention, the inventors have recognized at least the following problems in the prior art.

Due to manufacture errors, the distance between the heat source of an electronic product and an heat dispersion device is not constant, which may vary in a certain range. However, most existing heat conducting mediums are unable to self-adapt to an appropriate thickness to fit variations in distance between the heat source and the heat dispersion device, leading to higher thermal resistance between the heat source and the heat dispersion device, preventing rapid heat conduction consequently.

### SUMMARY OF THE INVENTION

A heat conducting device with high thermal conductivity and reliability and an electronic device applying the same heat conducting device are provided in embodiments of this invention.

A heat conducting device, comprising a first heat conducting board and a heat conducting structure is provided. The first heat conducting board comprises an upper heat conducting arm provided on one surface of the first heat conducting board. The heat conducting structure slidably abuts on the upper heat conducting arm of the first heat conducting board to form a contact surface through which heat transfer is realized. The heat conducting structure comprises a heat conducting surface, which is used to keep the relative position of the first heat conducting board and the heat conducting surface. The distance between the first heat conducting board and the heat conducting surface of the heat conducting structure may be varied by means of relative sliding between the upper heat conducting arm and the heat conducting structure, at the same time, it is ensured that a contact surface for heat transfer always exists between the upper heat conducting arm of the first heat conducting board and the heat conducting structure.

An electronic device applying the above heat conducting device is provided. The electronic device comprises a circuit board, multiple chips provided on the circuit board, a heat dispersing shield provided on the circuit board for accommodating the chips, a heat dispersion device provided on the heat dispersing shield, and multiple heat conducting devices. The multiple heat conducting devices are provided between the chips and the heat dispersing shield. First heat conducting boards of the heat conducting devices are closely adhered to the chips, the heat conducting structures of the heat conducting devices tightly abut on the heat dispersing shield through their heat conducting surfaces.

The heat conducting device and the electronic device applying the heat conducting device provided in embodiments of this invention may adjust its own thickness through sliding between an upper heat conducting arm and a lower heat conducting arm according to different use environments and manufacture errors to fit variations in distance between a heat source and a heat dispersing structure, so that effective heat conduction of electronic products can be guaranteed and heat dispersion effect can be improved.

### BRIEF DESCRIPTION OF THE DRAWINGS

FIG. 1 is a side view of a heat conducting device provided according to a first embodiment of this invention;

FIG. 2 is a side view of a heat conducting device provided according to a second embodiment of this invention;

FIG. 3 is a side view of a heat conducting device provided according to a third embodiment of this invention;

FIG. 4 is a side view of a heat conducting device provided according to a fourth embodiment of this invention;

FIG. 5 is a side view of a heat conducting device provided according to a fifth embodiment of this invention;

FIG. 6 is a perspective exploded view of a heat conducting device provided according to the fifth embodiment of this invention;

FIG. 7 is a side view of a heat conducting device provided according to a sixth embodiment of this invention;

FIG. 8 is a side view of a heat conducting device provided according to a seventh embodiment of this invention;

FIG. 9 is a side view of another heat conducting device provided according to the seventh embodiment of this invention;

FIG. 10 is a side view of a third heat conducting device provided according to the seventh embodiment of this invention;

FIG. 11 is a side view of a heat conducting device provided according to an eighth embodiment of this invention;

FIG. 12 is a side view of a heat conducting device provided according to a ninth embodiment of this invention;

FIG. 13 is a perspective schematic view of the heat conducting structure of the heat conducting device of FIG. 12;

FIG. 14 is a side view of a heat conducting device provided according to a tenth embodiment of this invention;

FIG. 15 is a perspective schematic view of the heat conducting structure of the heat conducting device of FIG. 14;

FIG. 16 is a side view of another heat conducting device provided according to the tenth embodiment of this invention;

FIG. 17 is a side view of another electronic device provided according to the eleventh embodiment of this invention.

### DETAILED DESCRIPTION OF THE PREFERRED EMBODIMENT

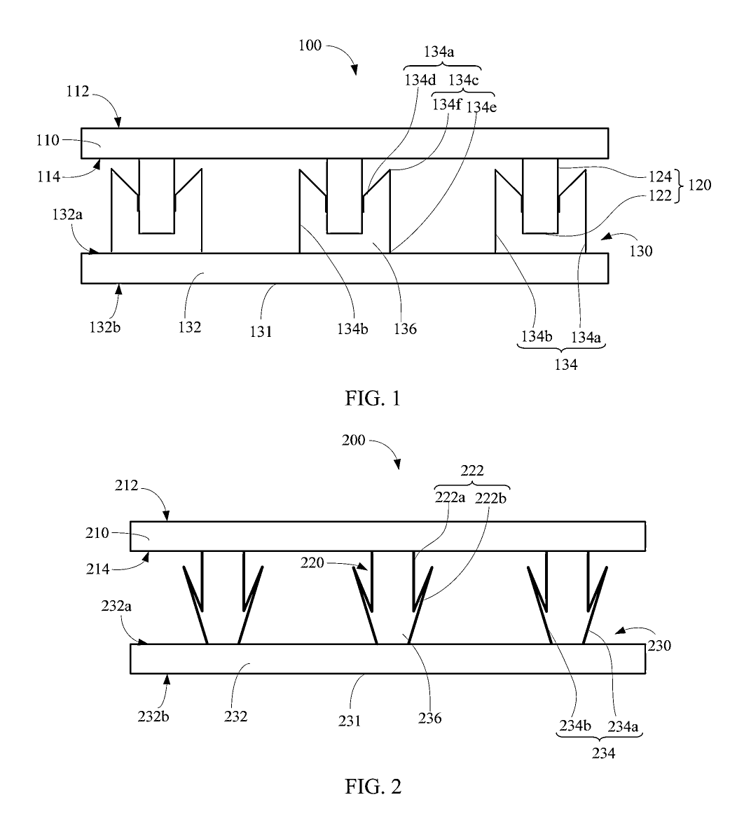

Referring to FIG. 1, FIG. 1 is a side view of a heat conducting device 100 provided in a first embodiment of this invention. The heat conducting device 100 comprises a first heat conducting board 110 and a heat conducting structure 130. The first heat conducting board 110 comprises at least one upper heat conducting arm 120 provided on a side surface of the first heat conducting board 110. The heat conducting structure 130 slidably abuts on the upper heat conducting arm 120 of the first heat conducting board 110 to form a contact surface through which heat transfer is performed. The heat conducting structure 130 comprises a heat conducting surface 131 contacting with a heat source or a heat dispersion device, the heat conducting structure 130 is used to keep a relative position of the first heat conducting board 110 and the heat conducting surface 131, and the distance between the first heat conducting board 110 and the heat conducting surface 131 of the heat conducting structure 130 may be varied by means of relative sliding between the upper heat conducting arm 120 and the heat conducting structure 130, at the same time, it is ensured that a contact surface for heat transfer always exists between the upper heat conducting arm 120 of the first heat conducting board 110 and the heat conducting structure 130.

The first heat conducting board 110 comprises a first surface 112 and a second surface 114 opposite to the first surface 112. The upper heat conducting arm 120 is formed on the second surface 114 of the first heat conducting board 110. It may be understood that the upper heat conducting arm 120 may be integrally formed with the first heat conducting board 110 or may be manufactured separately and then mounted to the first heat conducting board 110 through weld, screw connection, or other mechanical connection manner The first heat conducting board 110 and the upper heat conducting arm 120 are both formed by a metal with good thermal conductivity such as copper, aluminum, or a non-metal solid material such as graphite, boron nitride, and aluminum nitride, etc.

Each of the upper heat conducting arms 120 comprises an end surface 122 and a side surface 124 perpendicularly surrounding the periphery of the end surface 122. Because the end surface 122 is perpendicular to the side surface 124, the shape of the end surface 122 may reflect the shape of the cross section of the upper heat conducting arm 120, the end surface 122 of the upper heat conducting arm 120 may be arranged to any shape as demand, for example, a regular polygon such as an equiangular triangle, a square, a rectangle, or an irregular polygon or a circle, an ellipse, etc. In this embodiment, the side surface 124 of the upper heat conducting arm 120 and the heat conducting structure 130 abut with each other.

In this embodiment, the heat conducting structure 130 comprises a second heat conducting board 132 and multiple groups of lower heat conducting arms 134 formed on the second heat conducting board 132 and mutually abutted with the upper heat conducting arms 120. The second heat conducting board 132 comprises an upper surface 132a and a lower surface 132b opposite to the upper surface 132a. In this embodiment, the heat conducting surface 131 and the lower surface 132b of the second heat conducting board 132 are the same surface. The lower heat conducting arms 134 are provided on the upper surface 132a of the second heat conducting board 132 and form an angle with the upper surface 132a, wherein the angle has an optimal value of 90 degrees. Each group of the lower heat conducting arms 134 comprises two heat conducting reeds 134a, 134b having the same structure and symmetrically provided on the upper surface 132a of the second heat conducting board 132. For concision, the structure of heat conducting reeds 134a, 134b will be described with the heat conducting reed 134a as an example. Each of the heat conducting reeds 134a comprises a support portion 134c and a resilient portion 134d formed at one end of the support portion 134c. The support portion 134c comprises a fixed end 134e and a free end 134f corresponding to the fixed end 134e. The support portion 134c is fixed on the upper surface 132a of the second heat conducting board 132 via fixed end 134e of the support portion 134c. The resilient portion 134d is coupled on the free end 134f of the support portion 134c and forms an angle with the support portion 134c, preferably, a sharp angle. The resilient portions 134d of the two heat conducting reeds 134a, 134b of each group of lower heat conducting arms 134 face with each other and are spaced with a distance to form a receiving space 136 for receiving an upper heat conducting arm 120. In this embodiment, the lower heat conducting arms 134 are formed by beryllium bronze, spring steal, etc. It can be understood that the lower heat conducting arm 134 and the upper heat conducting arms 120 are exchangeable in position, that is, the lower heat conducting arms 134 can be provided on the second surface 114 of the first heat conducting board 110 and the upper heat conducting arms 120 can be correspondingly provided on the upper surface 132a of the second heat conducting board 132.

In use, an upper heat conducting arm 120 on the first heat conducting board 110 corresponds to a corresponding group of heat conducting reeds 134a, 134b on the heat conducting structure 130, and the end surface 122 of the upper heat conducting arm 120 is abutted against the resilient portions 134d of the heat conducting reeds 134a, 134b. Then, a prepressure is applied on the first heat conducting board 110 to insert the upper heat conducting arm 120 into the receiving space 136 of a corresponding lower heat conducting arm 134. Under the pressure, the resilient portion 134d of each of the heat conducting reeds 134a, 134b resilientally bends in the direction of the support portion 134c, and the bent resilient portion 134d closely abut against the side surface 124 of the upper heat conducting arm 120 to keep effective heat transfer through a contact surface between the heat conducting reeds 134a, 134b and the upper heat conducting arm 120, at the same time, to keep a relative position between the heat conducting surface 131 of the heat conducting structure 130 and the first heat conducting board 110. When the distance between the heat conducting surface 131 of the heat conducting structure 130 and the first heat conducting board 110 is required to be adjusted, it is only needed to apply a pressure on the first heat conducting board 110 or release the pressure applied on the first heat conducting board 110 to realize the adjustment of the distance between the heat conducting surface 131 of the heat conducting structure 130 and the first heat conducting board 110 through relative sliding between the heat conducting structure 130 and the first heat conducting board 110. When such a heat conducting device 100 is used in an electronic device, accumulative tolerances produced in the manufacture of the electronic device can be compensated to achieve the purpose of facilitating assembly and manufacture, at the same time, the effectiveness of the heat conducting path can be guaranteed, and heat dispersion effect can be improved during the use of the electronic product.

Referring to FIG. 2, FIG. 2 is a side view of a heat conducting device 200 provided according to a second embodiment of this invention. The structure of the heat conducting device 200 is similar to that of the heat conducting device 100 of the first embodiment, comprising a first heat conducting board 210 and a heat conducting structure 230, wherein the first heat conducting board 210 comprises at least one upper heat conducting arm 220 provided on one side surface of the first heat conducting board 210. The heat conducting structure 230 is directly aligned to the upper heat conducting arm 220 of the first heat conducting board 210 and slidably abuts against the upper heat conducting arm 220 to perform heat transfer through the contact surface between the heat conducting structure 230 and the upper heat conducting arm 220. The heat conducting structure 230 comprises a heat conducting surface 231, the heat conducting structure 230 is used to keep the relative position between the first heat conducting board 210 and the heat conducting surface 231, and the distance between the first heat conducting board 210 and the heat conducting surface 231 of the heat conducting structure 230 can be varied by means of relative sliding between the upper heat conducting arm 220 and the heat conducting structure 230, at the same time, it is ensured that a contact surface for heat transfer always exists between the upper heat conducting arm 220 of the first heat conducting board 210 and the heat conducting structure 230. The heat conducting device 200 provided in the second embodiment differs from the heat conducting device 100 provided in the first embodiment in the following aspects.

In this embodiment, each upper heat conducting arm 220 comprises two structure symmetric resilient sheets 222, wherein each resilient sheet 222 comprises a connecting segment 222a and an abutting segment 222b connected to the connecting segment 222a. The connecting segment 222a is connected to a second surface 114 of the first heat conducting board 210 at one end and forms an angle with the second surface 114, optimally an angle of 90 degrees. The abutting segment 222b is connected to the end of the connecting segment 222a apart from the first heat conducting board 210, and forms an angle with the connecting segment 222a, preferably, a sharp angle. The two resilient sheets 222 of each upper heat conducting arm 220 are symmetrically arranged on the second surface 214 of the first heat conducting board 210, and the abutting segments 222b of the two resilient sheets 222 are located on departure sides of the two connecting segment 222a of the two resilient sheets 222 respectively, so that a taper with a cross section gradually reduced along the direction of from a position close to the first heat conducting board 210 toward a position apart from the first heat conducting board 210 is formed.

In this embodiment, the heat conducting structure 230 comprises a second heat conducting board 232 and multiple groups of lower heat conducting arms 234 formed on the second heat conducting board 232 and mutually abutted with the upper heat conducting arms 220. The second heat conducting board 232 comprises an upper surface 232a and a lower surface 232b opposite to the upper surface 232a. In this embodiment, the heat conducting surface 231 and the lower surface 232b of the second heat conducting board 232 are the same surface. The lower heat conducting arms 234 are provided on the upper surface 232a of the second heat conducting board 232 and form an angle with the upper surface 232a, optimally an angle of 90 degrees. Each group of the lower heat conducting arms 234 comprises two heat conducting reeds 234a, 234b having the same structure and symmetrically arranged on the upper surface 232a of the second heat conducting board 232. In this embodiment, the heat conducting reeds 234a, 234b are leaf springs perpendicularly provided on the second heat conducting board 232 and spaced with a distance to form a receiving space 236 for receiving an upper heat conducting arm 220. In this embodiment, each of the upper heat conducting arms 220 and lower heat conducting arms 234 is formed by a resilient material such as beryllium bronze, spring steal, etc. It can be understood that the lower heat conducting arms 234 and the upper heat conducting arms 220 are exchangeable in position, that is, the lower heat conducting arms 234 can be provided on the second surface 114 of the first heat conducting board 210 and the upper heat conducting arms 220 can be correspondingly provided on the upper surface 232a of the second heat conducting board 232.

In use, each upper heat conducting arm 220 on the first heat conducting board 210 corresponds to a corresponding group of heat conducting reeds 234a, 234b on the heat conducting structure 230 to abut the abutting segments 222b of the upper heat conducting arm 220 against the heat conducting reeds 234a, 234b. Then, a prepressure is applied on the first heat conducting board 210 to insert the upper heat conducting arm 220 into the receiving space 236 of the corresponding lower heat conducting arm 234. The resilient sheets 222 of the upper heat conducting arm 220 and the heat conducting reeds 234a, 234b mutually abutted with the resilient sheets 222 produce a resilient deformation under the prepressure, a resilient restoring force produced by the resilient deformation make the abutting segments 222b of the upper heat conducting arm 220 closely abutted against the heat conducting reeds 234a, 234b, so as to keep effective heat transfer through a contact surface between the heat conducting reeds 234a, 234b and the resilient sheets 222, at the same time, to keep the relative position between the heat conducting surface 231 of the heat conducting structure 230 and the first heat conducting board 210. When the distance between the heat conducting surface 231 of the heat conducting structure 230 and the first heat conducting board 210 is required to be adjusted, it is only needed to apply a pressure on the first heat conducting board 210 or release the pressure applied on the first heat conducting board 210 to realize the adjustment of the distance between the heat conducting surface 231 of the heat conducting structure 230 and the first heat conducting board 210 through relative sliding between the heat conducting structure 230 and the first heat conducting board 210. When such a heat conducting device 200 is used in an electronic device, accumulative tolerances produced in the manufacture of the electronic device can be compensated. Furthermore, position adjustment and heat transfer functions are realized through employing correspondingly provided resilient sheets 222 and heat conducting reeds 234a, 234b, making the whole heat conducting device 200 lightened and simplified in structure.

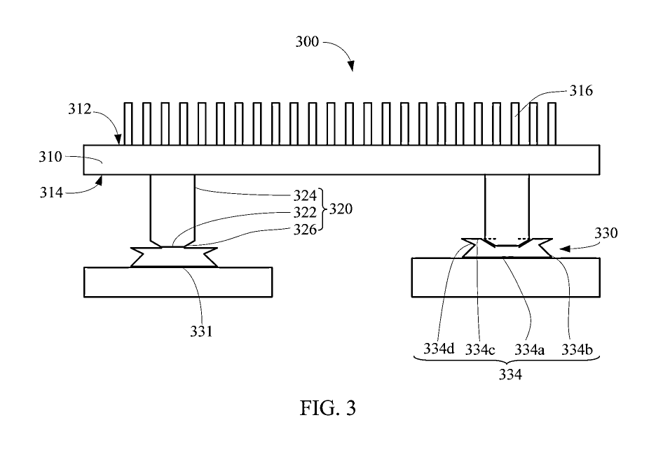

Referring to FIG. 3, FIG. 3 is a side view of a heat conducting device 300 provided according to a third embodiment of this invention. The structure of the heat conducting device 300 is similar to that of the heat conducting device 100 of the first embodiment, comprising a first heat conducting board 310 and a heat conducting structure 330, wherein the first heat conducting board 310 comprises at least one upper heat conducting arm 320 provided on a side surface of the first heat conducting board 310. The heat conducting structure 330 is directly aligned to the upper heat conducting arm 320 of the first heat conducting board 310 and slidably abuts against the upper heat conducting arm 320 to perform heat transfer through the contact surface between the heat conducting structure 330 and the upper heat conducting arm 320. The heat conducting structure 330 comprises a heat conducting surface 331 and is used to keep a relative position between the first heat conducting board 310 and the heat conducting surface 331. The distance between the first heat conducting board 310 and the heat conducting surface 331 of the heat conducting structure 330 can be varied by means of relative sliding between the upper heat conducting arm 320 and the heat conducting structure 330, at the same time, it is ensured that a contact surface for heat transfer always exists between the upper heat conducting arm 320 of the first heat conducting board 310 and the heat conducting structure 330. The heat conducting device 300 provided in the third embodiment differs from the heat conducting device 100 provided in the first embodiment in the following aspects.

In this embodiment, multiple heat dispersing fins are constructed, which are regularly arranged on a first surface 312 of the first heat conducting board 310 and are used to rapidly disperse heat of the first heat conducting board 310 to the surrounding medium.

In this embodiment, a taper side 326 is formed between the end surface 322 and side surface 324 of each upper heat conducting arm 320, which is connected between the side surface 324 and the end surface 322 with a connection angle, preferably a blunt angle.

In this embodiment, the heat conducting structure 330 comprises at least one mutually separated boom-type lower heat conducting arm 334. The multiple lower heat conducting arms 334 have the same structure, each of which comprises a locating segment 334a, two resilient segments 334b connected to the opposite sides of the locating segment 334a respectively, and two resilient boom segments 334c connected to corresponding ends of the resilient segments 334b. The bottom of the locating segment 334a forms the heat conducting surface 331. The two resilient segments 334b are connected to the opposite sides of the locating segment 334a with a certain angle. In order to make the resilient segments 334b resilient enough, the middle portions of the two resilient segments 334b are folded in opposite directions to form energy storage portions 334d. The two resilient boom segments 334c are connected to one the ends of the resilient segments 334b apart from the locating segment 334a by means of substantially parallel to the locating segment 334a, and are opposite to each other. It may be understood that the two resilient boom segments 334c may have their corresponding ends connected to form an integral structure which is connected to the resilient segments 334b at two ends.

In use, each upper heat conducting arm 320 on the first heat conducting board 310 corresponds to two resilient boom segments 334c of the heat conducting structure 330, and the end surface 322 of the each upper heat conducting arm 320 is abutted against the resilient boom segments 334c. Then, a prepressure is applied on the first heat conducting board 310 to insert the upper heat conducting arm 320 between the two resilient segments 334b of the corresponding boom-type lower heat conducting arm 334. The resilient boom segments 334c of the boom-type lower heat conducting arm 334 produce a resilient deformation toward the locating segment 334a under the prepressure. At that point, the taper side 326 formed on the upper heat conducting arm 320 is closely abutted against the folded resilient boom segments 334c, so that the upper heat conducting arm 320 sufficiently contacts the heat conducting structure 330 to guarantee effective heat transfer through the contact surface between the upper heat conducting arm 320 and the heat conducting structure 330, at the same time, to keep a relative position between the heat conducting surface 331 of the heat conducting structure 330 and the first heat conducting board 310. It is only needed to apply a pressure on the first heat conducting board 310 or release the pressure applied on the first heat conducting board 310 to realize the adjustment of the distance between the heat conducting surface 331 of the heat conducting structure 330 and the first heat conducting board 310 through relative sliding between the heat conducting structure 330 and the first heat conducting board 310. When such a heat conducting device 300 is used in an electronic device, accumulative tolerances produced in the manufacture of the electronic device can be compensated. Furthermore, the multiple mutually separated boom-type lower heat conducting arm 334 on the heat conducting structure 330 have their own locating segments 334a, so that such a heat conducting structure 330 can be applied in an electronic device having multiple separated heat sources simultaneously to simplify the heat dispersing structure and reduce manufacture cost.

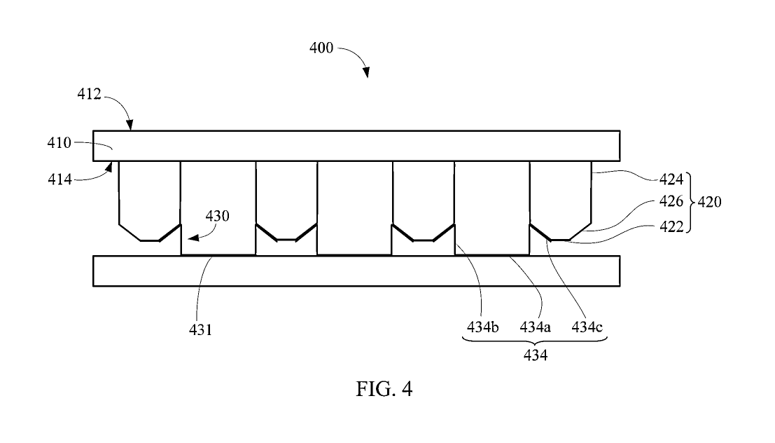

Referring to FIG. 4, FIG. 4 is a side view of a heat conducting device 400 provided according to a fourth embodiment of this invention. The structure of the heat conducting device 400 is similar to that of the heat conducting device 300 of the third embodiment, comprising a first heat conducting board 410 and a heat conducting structure 430, wherein the first heat conducting board 410 comprises two upper heat conducting arms 420 spaced at a distance and provided on a side surface of the first heat conducting board 410. The heat conducting structure 430 is directly aligned to the upper heat conducting arms 420 of the first heat conducting board 410 and slidably abuts against the upper heat conducting arm 420 to perform heat transfer through the contact surface between the heat conducting structure 430 and the upper heat conducting arms 420. The heat conducting structure 430 comprises a heat conducting surface 431 and is used to keep a relative position between the first heat conducting board 410 and the heat conducting surface 431. The distance between the first heat conducting board 410 and the heat conducting surface 431 of the heat conducting structure 430 can be varied by means of relative sliding between the upper heat conducting arms 420 and the heat conducting structure 430, at the same time, it is ensured that a contact surface for heat transfer always exists between the upper heat conducting arms 420 of the first heat conducting board 410 and the heat conducting structure 430. The heat conducting device 400 provided in the fourth embodiment differs from the heat conducting device 300 provided in the third embodiment in the following aspects.

In this embodiment, the heat conducting structure 430 comprises multiple mutually separated boom-type lower heat conducting arms 434. The multiple boom-type lower heat conducting arms 434 have the same structure, and correspond to spacing regions between the multiple upper heat conducting arms 420 of the first heat conducting board 410. Each of the lower heat conducting arms 434 comprises a locating segment 434a, two resilient segments 434b connected to the opposite sides of the locating segment 434a respectively, and two resilient boom segments 434c connected to corresponding ends of the resilient segments 434b. The bottom of the locating segment 434a forms the heat conducting surface 431. The two resilient segments 434b are connected to the opposite sides of the locating segment 434a with a certain angle. The two resilient boom segments 434c are connected to the ends of the resilient segments 434b apart from the locating segment 434a along departure directions and are folded toward the locating segment 434a.

In use, each upper heat conducting arm 420 on the first heat conducting board 410 corresponds to adjacent resilient boom segments 434c of two adjacent boom-type lower heat conducting arms 434 of the heat conducting structure 430, and the end surface 422 of the upper heat conducting arm 420 is abutted against the resilient boom segments 434c. Then, a prepressure is applied on the first heat conducting board 410 to insert the upper heat conducting arm 420 between the two adjacent boom-type lower heat conducting arms 434. The resilient boom segments 434c of the adjacent boom-type lower heat conducting arm 434 produce a resilient deformation toward the locating segment 434a under the prepressure. At that point, a taper side 426 formed on the upper heat conducting arm 420 is closely abutted against the folded resilient boom segments 434c to cause sufficiently contact between the upper heat conducting arm 420 and the heat conducting structure 430, so as to guarantee effective heat transfer through the contact surface between the upper heat conducting arm 420 and the heat conducting structure 430, and keep a relative position between the heat conducting surface 431 of the heat conducting structure 430 and the first heat conducting board 410 at the same time. The adjustment manner of the heat conducting device 400 provided in this embodiment is as same as that of the heat conducting device 300 provided in the third embodiment, and have the same advantages as the heat conducting device 300.

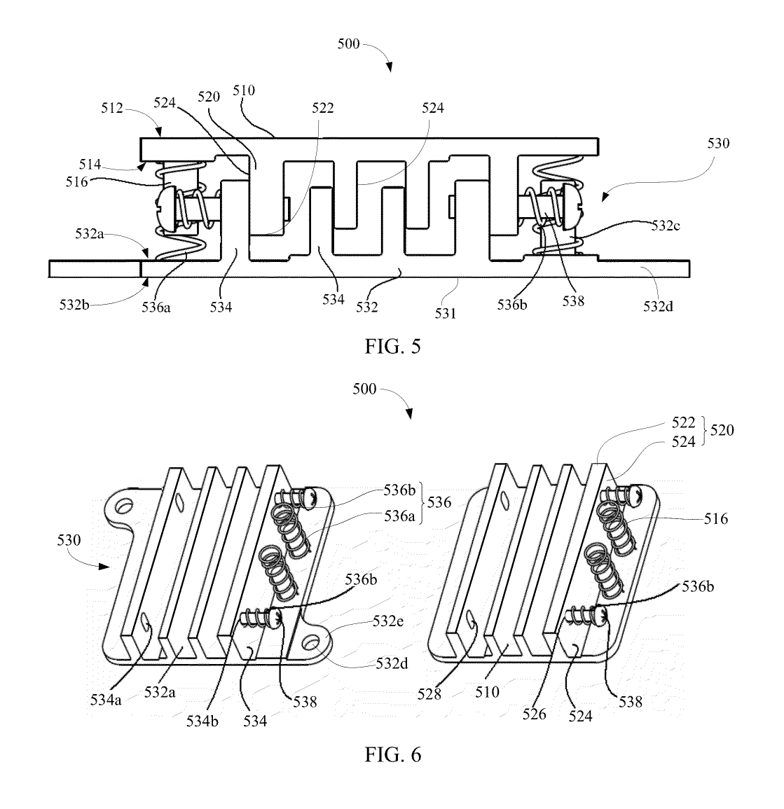

Referring to FIG. 5, FIG. 5 is a side view of a heat conducting device 500 provided according to a fifth embodiment of this invention. The heat conducting device 500 comprises a first heat conducting board 510 and a heat conducting structure 530, wherein the first heat conducting board 510 comprises at least one upper heat conducting arm 520 provided on a side surface of the first heat conducting board 510. The heat conducting structure 530 is directly aligned to the upper heat conducting arm 520 of the first heat conducting board 510 and slidably abuts against the upper heat conducting arm 520 to perform heat transfer through the contact surface between the heat conducting structure 530 and the upper heat conducting arms 520. The heat conducting structure 530 comprises a heat conducting surface 531 and is used to keep a relative position between the first heat conducting board 510 and the heat conducting surface. The distance between the first heat conducting board 510 and the heat conducting surface 531 of the heat conducting structure 530 can be varied by means of relative sliding between the upper heat conducting arms 520 and the heat conducting structure 530, at the same time, it is ensured that a contact surface for heat transfer always exists between the upper heat conducting arms 520 of the first heat conducting board 510 and the heat conducting structure 530.

The first heat conducting board 510 comprises a first surface 512 and a second surface 514 opposite to the first surface 512. Two first locating posts 516 are formed on the second surface 514 of the first heat conducting board 510, in this embodiment, the locating posts 516 are formed on the second surface 514 at positions close to an edge of the second surface 514, but not limited to the above positions, the locating posts 516 can be provided on the second surface 514 at any required positions capable of ensuring the normal use of the heat conducting device 500.

This embodiment comprises multiple upper heat conducting arms 520 spaced at a certain distance and distributed on the first heat conducting board 510. The multiple upper heat conducting arms 520 are multiple plate structures provided on the second surface 514 of the first heat conducting board 510 in parallel. It may be understood that the upper heat conducting arms 520 may be integrally formed with the first heat conducting board 510, or may be separately manufactured and then mounted to the first heat conducting board 510 through weld, screw connection or adherence. The first heat conducting board 510 and the upper heat conducting arms 520 are formed by a metal with good thermal conductivity such as copper, aluminum, or a non-metal solid material such as graphite, boron nitride, and aluminum nitride, etc.

Referring to FIG. 6 also, FIG. 6 is a perspective exploded view of a heat conducting device 500 provided according to the fifth embodiment of this invention. Each of the upper heat conducting arms 520 comprises an end surface 522 and a side surface 524 perpendicularly surrounding the periphery of the end surface 522. Because the end surface 522 is perpendicular to the side surface 524, the shape of the end surface 522 may represent the shape of the cross section of the upper heat conducting arm 520, the end surface 522 of the upper heat conducting arm 520 may be arranged to any shape as required, for example a regular polygon such as an equiangular triangle, a square, a rectangle, or an irregular polygon or a circle, an ellipse, etc. In this embodiment, the side surface 524 of the upper heat conducting arm 520 is abutted against the heat conducting structure 530. In this embodiment, multiple first screw holes 526 and multiple first sliding holes 528 are provided on two outermost upper heat conducting arms 520 among the multiple upper heat conducting arms 520, wherein the first screw holes 526 are provided on a same upper heat conducting arm 520 and the first sliding holes 528 are provided on the other upper heat conducting arm 520.

In this embodiment, the heat conducting structure 530 comprises a second heat conducting board 532, multiple lower heat conducting arms 534 formed on the second heat conducting board 532, multiple resilient elements 536 and multiple locking elements 538.

The second heat conducting board 532 comprises an upper surface 532a and a lower surface 532b opposite to the upper surface 532a. In this embodiment, the heat conducting surface 531 and the lower surface 532b of the second heat conducting board 532 are the same surface. Two second locating posts 532c are formed on the upper surface 532a of the second heat conducting board 532, which are symmetrically distributed in space with the first locating posts 516 on the first heat conducting board 510, that is, the orthogonal projections of the first locating posts 516 and the second locating posts 532c on a plane where the second surface 514 of the first heat conducting board 510 locates are symmetrically distributed with respect to the geometric center of the second surface 514. The second heat conducting board 532 is square in shape, and two lips 532d are formed at diagonal positions of the second heat conducting board 532, with two through holes 532e provided on the two lips 532d for securing the second heat conducting board 532 to an attachment, such as a heat source or a heat dispersing shield in an electronic device, by fasteners passing through the through holes 532e. It may be understood that the lips 532d can be arranged on the second heat conducting board 532 at any positions, so long as they are symmetrical in structure such that the second heat conducting board 532 can be steadily mounted on an attachment.

The multiple lower heat conducting arms 534 are disposed on the upper surface 532a of the second heat conducting board 532 in the same arrangement as the upper heat conducting arms 520. Two outermost lower heat conducting arms 534 of the multiple lower heat conducting arms 534 are provided with second sliding holes 534a and second screw holes 534b corresponding to the first screw holes 526 and the first sliding holes 528 on the upper heat conducting arms 520 respectively, wherein the hole diameter of the first sliding holes 528 and the second sliding holes 534a is larger than the hole diameter of the first screw holes 526 and second screw holes 534b, and the first sliding holes 528 and the second sliding holes 534a extend a distance along a direction vertical to the first heat conducting board 510 to form elongate holes with a run space.

In this embodiment, the resilient elements 536 comprise multiple first limit resilient elements 536a and multiple second limit resilient elements 536b. The multiple first limit resilient elements 536a are used to set around the first locating posts 516 and the second locating posts 532c to keep a distance between the first heat conducting board 510 and the heat conducting surface 531 of the heat conducting structure 530. The multiple second limit resilient elements 536b are used to match the locking elements 538 to ensure that the upper heat conducting arms 520 and the lower heat conducting arms 534 are closely abutted with each other all the time. In this embodiment, the resilient elements 536 are coil springs.

In this embodiment, the locking elements 538 are bolts, which are used to slidably connect the first heat conducting board 510 and heat conducting structure 530.

When assembled, first of all, the first limit resilient elements 536a are set around the first locating posts 516 and the second locating posts 532c respectively, then the first heat conducting board 510 is directly covered on the heat conducting structure 530 such that the upper heat conducting arm 520 and lower heat conducting arms 534 are alternately arranged, wherein the multiple upper heat conducting arm 520 are located on the same side of the lower heat conducting arms 534. Next, a pressure is applied on the first heat conducting board 510 to cause a resilient deformation of the first limit resilient elements 536a to store an amount of elastic potential energy, an elastic force is provided by the elastic potential energy stored in the first limit resilient elements 536a to keep the position relationship between the first heat conducting board 510 and the heat conducting structure 530. At the same time, the first screw holes 526 and the first sliding holes 528 on the upper heat conducting arm 520 are aligned with the second sliding holes 534a and the second screw holes 534b on the lower heat conducting arms 534. Then, the locking elements 538 setting around second limit resilient elements 536b are locked into the first screw holes 526 and the second screw holes 534b, and ensure that the locking elements 538 pass into the first sliding holes 528 and the second sliding holes 534a, so that the upper heat conducting arms 520 and the lower heat conducting arms 534 move in the travel distance defined by the first sliding holes 528 and the second sliding holes 534a. A pretightening force is applied on the locking elements 538, so that the second limit resilient elements 536b set around the locking elements 538 produce a resilient deformation to store an amount of elastic potential energy. The second limit resilient elements 536b provide a force applied on the upper heat conducting arms 520 and the lower heat conducting arms 534 through the elastic potential energy stored in the second limit resilient elements 536b to cause a trend of closing to each other of the upper heat conducting arms 520 and the lower heat conducting arms 534, to ensure that the upper heat conducting arms 520 and the lower heat conducting arms 534 closely contact all the time to realize heat transfer.

With the heat conducting device 500 provided in this embodiment, the relative position between the heat conducting surface 531 of the heat conducting structure 530 and the first heat conducting board 510 is kept through the locking elements 538 and the first limit resilient elements 536a. When the distance between the heat conducting surface 531 of the heat conducting structure 530 and the first heat conducting board 510 is required to be adjusted, it is only needed to apply a pressure on the first heat conducting board 510 or release the pressure applied on the first heat conducting board 510 to realize the adjustment of the distance between the heat conducting structure 530 and the first heat conducting board 510, so that accumulative tolerances produced in the manufacture of the electronic device can be compensated. Furthermore, through providing lower heat conducting arms 534 on second heat conducting board 532 which are abutted against upper heat conducting arms 520, the heat conducting device provided in this embodiment may increase the contact surface for heat transfer between the heat conducting structure 530 and the first heat conducting board 510, so that thermal resistance is reduced, and heat dispersion efficiency is further improved.

Referring to FIG. 7, FIG. 7 is a side view of a heat conducting device 600 provided according to a sixth embodiment of this invention. The structure of the heat conducting device 600 is similar to that of the heat conducting device 500 provided in the fifth embodiment, comprising a first heat conducting board 610 and a heat conducting structure 630. The first heat conducting board 610 comprises at least one upper heat conducting arm 620 provided on one side surface of the first heat conducting board 610. The heat conducting structure 630 directly faces the upper heat conducting arm 620 of the first heat conducting board 610 and slidably abuts against the upper heat conducting arm 620 to perform heat transfer through the contact surface between a lower heat conducting arm 634 on the heat conducting structure 630 and the upper heat conducting arm 620. The heat conducting structure 630 comprises a heat conducting surface 631 and is used to keep the relative position between the first heat conducting board 610 and the heat conducting surface. The distance between the first heat conducting board 610 and the heat conducting surface 631 of the heat conducting structure 630 can be varied by means of relative sliding between the upper heat conducting arm 620 and the heat conducting structure 630, at the same time, it is ensured that a contact surface for heat transfer always exists between the upper heat conducting arm 620 of the first heat conducting board 610 and the heat conducting structure 630. The heat conducting device 600 provided in the sixth embodiment differs from the heat conducting device 500 provided in the fifth embodiment in the following aspects.

In this embodiment, the first locating posts 516, the second locating posts 532c and the first limit resilient elements 536a set around the first locating posts 516 and the second locating posts 532c in the heat conducting device 500 in the fifth embodiment are omitted. Further, a first resilient element 650 arranged between the second surface 614 of the first heat conducting board 610 and the upper surface 632a of the second heat conducting board 632 is employed in this embodiment to keep the relative position between the first heat conducting board 610 and heat conducting surface 631 of the heat conducting structure 630. In this embodiment, the first resilient element 650 is located in the space surrounded by the upper heat conducting arm 620 and the lower heat conducting arm 634 together. In this embodiment, the first resilient element 650 is a spring sheet.

The heat conducting device 600 provided in the sixth embodiment of this invention may realize the same functions of the heat conducting device 500 provided in the fifth embodiment. Furthermore, the heat conducting device 600 employs a first resilient element 650 to keep the relative position between the first heat conducting board 610 and the heat conducting surface 631 of the heat conducting structure 630, so that the structure of the heat conducting device 600 is greatly simplified, and the manufacture cost of the heat conducting device 600 can be further reduced.

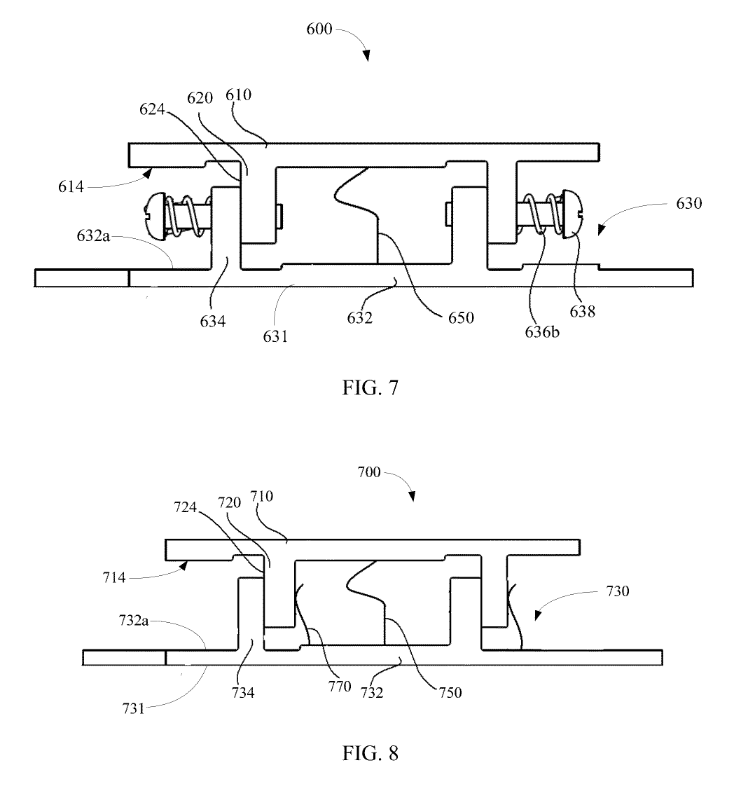

Referring to FIG. 8, FIG. 8 is a side view of a heat conducting device 700 provided according to a seventh embodiment of this invention. The structure of the heat conducting device 700 is similar to that of the heat conducting device 600 provided in the sixth embodiment, comprising a first heat conducting board 710 and a heat conducting structure 730. The first heat conducting board 710 comprises at least one upper heat conducting arm 720 provided on one side surface of the first heat conducting board 710. The heat conducting structure 730 is directly aligned to the upper heat conducting arm 720 of the first heat conducting board 710 and slidably abuts against the upper heat conducting arm 720 to perform heat transfer through the contact surface between the heat conducting structure 730 and the upper heat conducting arm 720. The heat conducting structure 730 comprises a heat conducting surface 731 and is used to keep the relative position between the first heat conducting board 710 and the heat conducting surface. The distance between the first heat conducting board 710 and the heat conducting surface 731 of the heat conducting structure 730 can be varied by means of relative sliding between the upper heat conducting arm 720 and the heat conducting structure 730, at the same time, it is ensured that a contact surface for heat transfer always exists between the upper heat conducting arm 720 of the first heat conducting board 710 and the heat conducting structure 730. The heat conducting device 700 provided in the seventh embodiment differs from the heat conducting device 600 provided in the sixth embodiment in the following aspects.

In this embodiment, the locking elements 638 and the second limit resilient elements 636b in the sixth embodiment are further omitted. Furthermore, two second resilient elements 770 provided on the supper surface 732a of the second heat conducting board 732 are employed in this embodiment, the second resilient elements 770 are adjacent to the lower heat conducting arms 734 and are abutted against the first heat conducting board 710, so that the upper heat conducting arms 720 on the first heat conducting board 710 are closely abutted against the lower heat conducting arms 734 of the heat conducting structure 730 to ensure that a contact surface for heat transfer always exists between the first heat conducting board 710 and the heat conducting structure 730. In order to make the contact of the contact surfaces more sufficient, a heat conductive filler, such as heat conductive silica gel, etc may be filled between the contact surfaces of the first heat conducting board 710 and the heat conducting structure 730. In this embodiment, the second resilient elements 770 are spring sheets, but not limited to spring sheets.

The heat conducting device 700 provided in the seventh embodiment of this invention may realize the same functions of the heat conducting device 600 provided in the sixth embodiment. Furthermore, the heat conducting device 700 employs two second resilient element 770 to keep the close abutting between the upper heat conducting arms 720 and the lower heat conducting arms 734, not only realizing effective heat transfer between the upper heat conducting arms 720 and the lower heat conducting arms 734, but also further simplifying the structure of the heat conducting device 700, further reducing the manufacture cost of the heat conducting device 700.

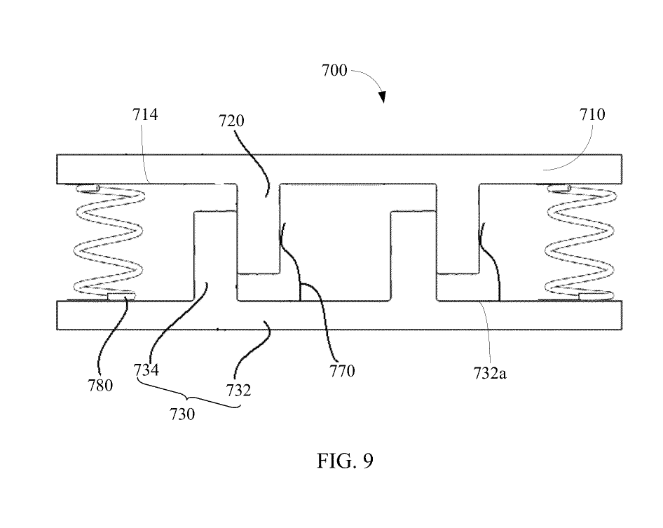

It may be understood that the first resilient element 750 may have other alternative solutions, referring to FIG. 9, the first resilient element 750 can be substituted by two resilient elements 780 disposed between the first heat conducting board 710 and the second heat conducting board 732. In this embodiment, the resilient elements 780 are symmetrically disposed on the periphery of the region surrounded by the upper heat conducting arms 720 and the lower heat conducting arms 734, but not limited to this region. The resilient elements 780 in this embodiment are metal coil springs, but not limited to metal coil springs. The resilient elements 780 may be substituted by elastic rubber or other elastic apparatus or elements.

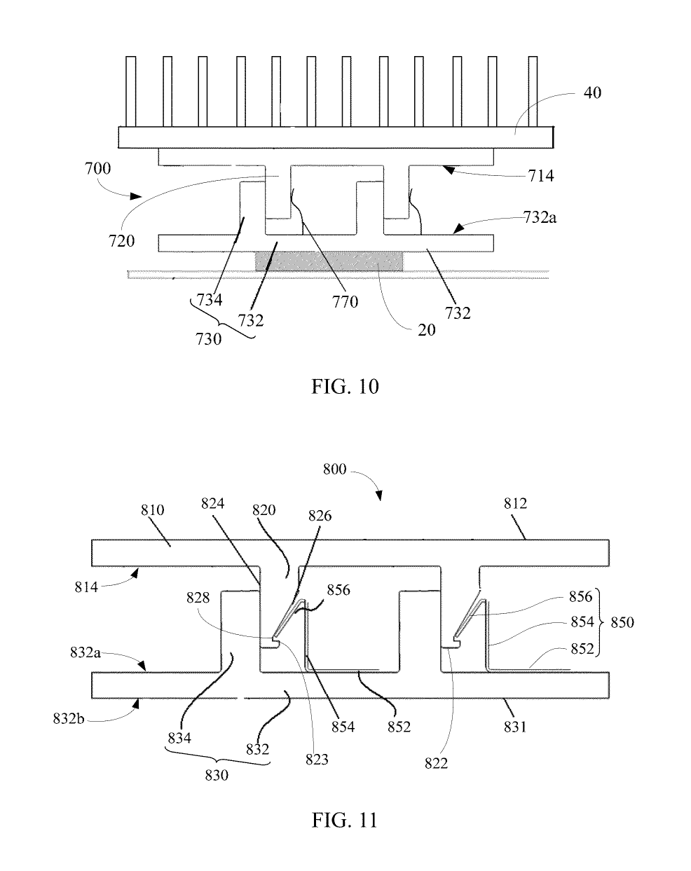

It may be understood that, as shown in FIG. 10, if the first heat conducting board 710 of the heat conducting device 700 and the second heat conducting board 732 of the heat conducting structure 730 are reliably connected to a heat source 20 of an electronic device and a heat dispersion device or case 40 corresponding to the heat source 20 through screw connection, riveting, adherence and other connection manners, the first resilient element 750 or the resilient elements 780 of the heat conducting device 700 can be both omitted, such that the structure of the heat conducting device 700 can be simplified further.

Referring to FIG. 11, FIG. 11 is a side view of a heat conducting device 800 provided according to an eighth embodiment of this invention. The structure of the heat conducting device 800 is similar to that of the heat conducting device 700 provided in the seventh embodiment, comprising a first heat conducting board 810 and a heat conducting structure 830. The first heat conducting board 810 comprises at least one upper heat conducting arm 820 provided on one side surface of the first heat conducting board 810. The heat conducting structure 830 is directly aligned to the upper heat conducting arm 820 of the first heat conducting board 810 and slidably abuts against the upper heat conducting arm 820 to perform heat transfer through the contact surface between the heat conducting structure 830 and the upper heat conducting arm 820. The heat conducting structure 830 comprises a heat conducting surface 831 and is used to keep the relative position between the first heat conducting board 810 and the heat conducting surface 831. The distance between the first heat conducting board 810 and the heat conducting surface 831 of the heat conducting structure 830 can be varied by means of relative sliding between the upper heat conducting arm 820 and the heat conducting structure 830, at the same time, it is ensured that a contact surface for heat transfer always exists between the upper heat conducting arm 820 of the first heat conducting board 810 and the heat conducting structure 830. The heat conducting device 800 provided in the eighth embodiment differs from the heat conducting device 700 provided in the seventh embodiment in the following aspects.

The first resilient element 750 and second resilient elements 770 of the heat conducting device 700 provided in the seventh embodiment are substituted with multiple integrated resilient elements 850 in the heat conducting device 800 provided in the eighth embodiment of this invention. The resilient elements 850 can not only keep the position relationship between the first heat conducting board 810 and the heat conducting structure 830, but also keep the close abutting between the upper heat conducting arms 820 and the lower heat conducting arms 834 to realize effective heat transfer between the first heat conducting board 810 and the heat conducting structure 830. Each of the resilient elements 850 comprises a locating segment 852, a supporting segment 854 connected to the locating segment 852, and a resilient segment 856 connected to an end of the supporting segment 854. The locating segment 852 is fixed on the upper surface 832a of the second heat conducting board 832. The supporting segment 854 is connected to an end of the locating segment 852 in a substantially vertical manner A positive or negative tolerance is allowed for the angle between the supporting segment 854 and the locating segment 852. The resilient segment 856 is connected to the end of the supporting segment 854 apart from the supporting segment 854, and is tilted towards the second heat conducting board 832. Corresponding to the titled resilient segment 856, a slant 826 is provided on a side 824 of the upper heat conducting arm 820. The slant 826 of the upper heat conducting arm 820 is abutted against the resilient segment 856 of a corresponding resilient element 850. The resilient segment 856 applies an elastic force on the slant 826 of the upper heat conducting arm 820, which can be decomposed into a push force perpendicular to the side 824 of the upper heat conducting arm 820 to keep the close abutting between the upper heat conducting arm 820 and the lower heat conducting arm 834, and a push force perpendicular to the end side 822 of the upper heat conducting arm 820 to keep the position relationship between the first heat conducting board 810 and the heat conducting structure 830. Therefore, the heat conducting device 800 provided in this embodiment may provide forces required to keep the position relationship between the first heat conducting board 810 and the heat conducting structure 830 and to keep the close abutting between the upper heat conducting arm 820 and the lower heat conducting arm 834, so that the structure of the heat conducting device 800 can be simplified. Furthermore, heat transfer also can be realized through the large area contact between the resilient element 850 and the second heat conducting board 832, the upper heat conducting arm 820, so that thermal conductivity between the first heat conducting board 810 and the heat conducting structure 830 can be improved. Furthermore, in order to prevent the escape of the upper heat conducting arm 820 from the resilient element 850 under the elastic force of the resilient element 850, the slant 826 is connected to the end side 822 of the upper heat conducting arm 820 through a transition surface 828 parallel to the side surface 824, and a block 823 protruding from the transition surface 828 is provided at a position on the transition surface 828 adjacent to the end side 822. The block 823 and the end of the resilient segment 856 of the resilient element 850 are abutted with each other to prevent the separation phenomenon of the upper heat conducting arm 820 and the resilient element 850.

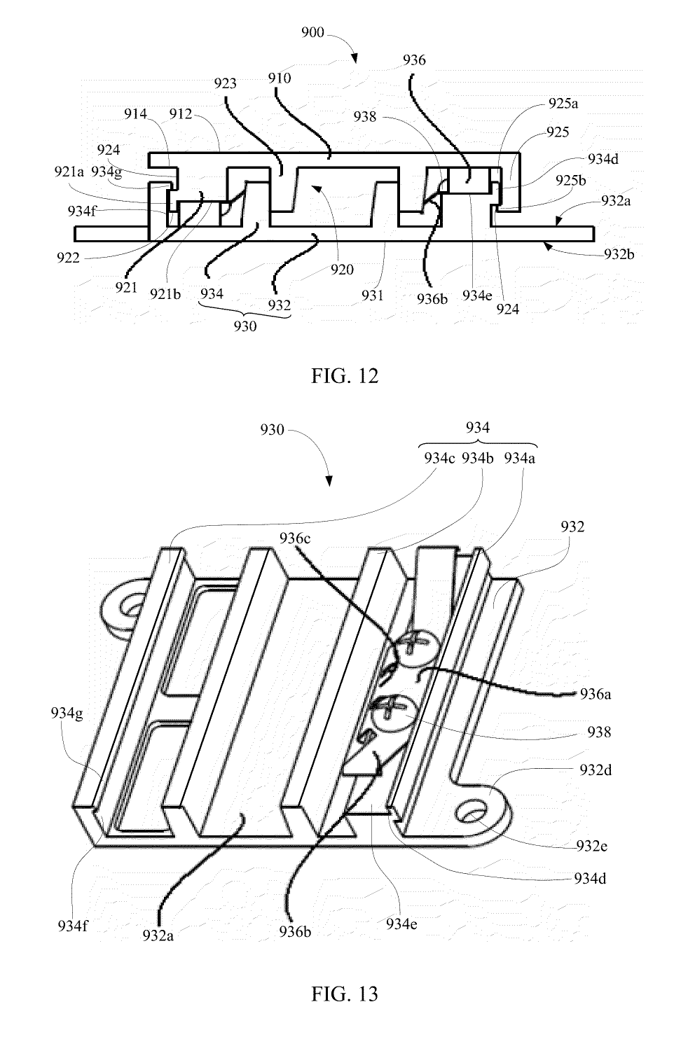

Referring to FIG. 12, FIG. 12 is a side view of a heat conducting device 900 provided according to a ninth embodiment of this invention. The heat conducting device 900 comprises a first heat conducting board 910 and a heat conducting structure 930. The first heat conducting board 910 comprises at least one upper heat conducting arm 920 provided on a side surface of the first heat conducting board 910. The heat conducting structure 930 is directly aligned to the upper heat conducting arm 920 of the first heat conducting board 910 and slidably abuts against the upper heat conducting arm 920 to perform heat transfer through the contact surface between the heat conducting structure 930 and the upper heat conducting arms 920. The heat conducting structure 930 comprises a heat conducting surface 931 and is used to keep a relative position between the first heat conducting board 910 and the heat conducting surface. The distance between the first heat conducting board 910 and the heat conducting surface 931 of the heat conducting structure 930 can be varied by means of relative sliding between the upper heat conducting arms 920 and the heat conducting structure 930, at the same time, it is ensured that a contact surface for heat transfer always exists between the upper heat conducting arm 920 of the first heat conducting board 910 and the heat conducting structure 930.

The first heat conducting board 910 comprises a first surface 912 and a second surface 914 corresponding to the first surface 912.

This embodiment comprises multiple upper heat conducting arms 920, containing a first upper heat conducting arm 921, two second upper heat conducting arms 923 and a third upper heat conducting arm 925. The first upper heat conducting arm 921, the second upper heat conducting arms 923 and the third upper heat conducting arm 925 are sequentially provided on a second surface 914 of the first heat conducting board 910. A first limit protrusion 921a protruding from a side surface 924 and flush with an end surface 922 of the first upper heat conducting arm 921 is provided on the side surface 924 of the first upper heat conducting arm 921 adjacent to an edge of the first heat conducting board 910. The first limit protrusion 921a is used to match with a corresponding limit structure on the heat conducting structure 930 to restrict the position between the first heat conducting board 910 and the heat conducting structure 930. A first groove 921b is provided on the end side 922 of the first upper heat conducting arm 921 to receive the limit device of the heat conducting structure 930. The two second upper heat conducting arms 923 are provided on one side of the first upper heat conducting arm 921 with an interval. The third upper heat conducting arm 925 is provided on the first heat conducting board 910 on one side of the second upper heat conducting arms 923 apart from the first upper heat conducting arm 921. A second groove 925a adjacent to the second surface 914 of the first heat conducting board 910 is provided on a side surface 924 of the third upper heat conducting arm 925 facing the first upper heat conducting arm 921, a second limit protrusion 925b is formed on one end of the second groove 925a apart from the first heat conducting board 910. The second limit protrusion 925b is used to match a corresponding limit structure on the heat conducting structure 930 to restrict the position between the first heat conducting board 910 and the heat conducting structure 930.

Referring to FIG. 13, FIG. 13 is a perspective schematic view of the heat conducting structure 930 provided in the ninth embodiment of this invention.

The heat conducting structure 930 comprises a second heat conducting board 932, multiple lower heat conducting arms 934 formed on the second heat conducting board 932, multiple resilient elements 936 and multiple locking elements 938.

The second heat conducting board 932 comprises an upper surface 932a and a lower surface 932b corresponding to the upper surface 932a. In this embodiment the heat conducting surface 931 and the lower surface 932b of the second heat conducting board 932 are the same surface. The second heat conducting board 932 is square in shape, two lips 932d are formed on diagonal positions of the second heat conducting board 932 respectively, with two through holes 932e provided on the two lips 932d for securing the second heat conducting board 932 to an attachment, such as a heat source or a heat dispersing shield in an electronic device by means of fasteners passing through the through holes 932e.

The structure and arrangement of the lower heat conducting arms 934 are as same as that of the upper heat conducting arms 920. The multiple lower heat conducting arms 934 comprises a first lower heat conducting arm 934a, two second lower heat conducting arms 934b, and a third lower heat conducting arm 934c. The first lower heat conducting arm 934a, the second lower heat conducting arms 934b, and the third lower heat conducting arm 934c are sequentially provided on the upper surface 932a of the second heat conducting board 932. A third limit protrusion 934d corresponding to and capable of clipping with the second limit protrusion 925b on the third upper heat conducting arm 925 protrudes from a side surface of the first lower heat conducting arm 934a adjacent to an edge of the second heat conducting board 932, and a third groove 934e is provided on the first lower heat conducting arm 934a at a position adjacent to the third limit protrusion 934d. The two second lower heat conducting arms 934b are provided on the second heat conducting board 932 on one side of the first lower heat conducting arm 934a at a certain interval. The third lower heat conducting arm 934c is provided on the second heat conducting board 932 on one side of the second lower heat conducting arms 934b apart from the first lower heat conducting arm 934a. A fourth groove 934f is formed on the third lower heat conducting arm 934c, corresponding to the first limit protrusion 921a on the first upper heat conducting arm 921, a fourth limit protrusion 934g capable of clipping with the first limit protrusion 921a is formed on one end of the fourth groove 934f apart from the upper surface 932a of the second heat conducting board 932.

The multiple resilient elements 936 are disposed in the first groove 921b and the third groove 934e respectively. Each of the resilient elements 936 comprises a fixing portion 936a, two first resilient arms 936b symmetrically formed on opposite sides of the fixing portion 936a, and a second resilient arm 936c provided on the fixing portion 936a and located at a side edge between the two first resilient arms 936b. The two first resilient arms 936b are folded an angle towards a direction vertical to the fixing portion 936a, preferably, the folding angle causes the folded first resilient arms 936b abutted against the first heat conducting board 910 and the second heat conducting board 932 when the second limit protrusion 925b is clipped with the third limit protrusion 934d and the first limit protrusion 921a is clipped with the fourth limit protrusion 934g. The second resilient arm 936c is folded an angle towards a direction opposite to the folding direction of the first resilient arms 936b, preferably, an angle causing that the second resilient arm 936c can abut against an adjacent upper heat conducting arm 920 or a lower heat conducting arm 934 when the first heat conducting board 910 is matched to the heat conducting structure 930.

When assembled, first of all, the fixing portion 936a of a resilient element 936 is secured on the underside of the first groove 921b or the third groove 934e through locking elements 938. Then, the first resilient arms 936b and the second resilient arm 936c of the resilient elements 936 is compressed, the first limit protrusion 921a and the second groove 925a of the first heat conducting board 910 are aligned with the fourth groove 934f and the third limit protrusion 934d of the heat conducting structure 930, and the first limit protrusion 921a slides into the fourth groove 934f from one side of the heat conducting structure 930, the third limit protrusion 934d slides into the second groove 925a, so that the first limit protrusion 921a and the second limit protrusion 925b of the first heat conducting board 910 clip with the fourth limit protrusion 934g and the third limit protrusion 934d of the heat conducting structure 930 respectively. Finally, the first resilient element 936b and the second resilient element 936c are released such that the first resilient element 936b abut against first heat conducting board 910 or second heat conducting board 932 corresponding to first resilient element 936b to keep the relative position between the first heat conducting board 910 and the heat conducting structure 930, at the same time, the second resilient element 936c abuts against the adjacent second upper heat conducting arm 920 or second lower heat conducting arm 934 to provide an elastic force causing the multiple upper heat conducting arms 920 and lower heat conducting arms 932 closely abutted to ensure that a contact surface for heat transfer always exists between the upper heat conducting arms 920 and the lower heat conducting arms 934. The assembly manner of the heat conducting device 900 is merely one manner for the introduction of this embodiment, and other assembly manners can be employed, such as the first heat conducting board 910 is directly disposed above the heat conducting structure 930 to make the spaces between the upper heat conducting arms 920 corresponding to the spaces between the lower heat conducting arms 934, then a press is applied on the first heat conducting board 910 by which the first resilient arms 936b and the second resilient arm 936c of the resilient element 936 produce elastic deformations, as the upper heat conducting arms 920 gradually insert into the spaces between the lower heat conducting arms 934, the second resilient element 936c abuts against the adjacent second upper heat conducting arm 920 or second lower heat conducting arm 934 and produces an elastic deformation, a trend of relative movement exists between the first heat conducting board 910 and the adjustable heat conducting structure 930 under the effect of the elastic force of the second resilient element 936c, with such a trend of movement, the first limit protrusion 921a and the second limit protrusion 925b of the first heat conducting board 910 clip with the fourth limit protrusion 934g and the third limit protrusion 934d of the heat conducting structure 930 respectively to complete the assembly of the heat conducting device 900.

The heat conducting device 900 provided in this embodiment may keep the relative position between the first heat conducting board 910 and the heat conducting structure 930, and ensure that a contact surface for heat transfer always exists between the first heat conducting board 910 and the heat conducting structure 930 through integrated resilient elements 936, so as to realize an adjustable distance between the first heat conducting board 910 and the heat conducting structure 930 and make sure good heat transfer property at the same time. Furthermore, employing integrated resilient elements 936 may simplify the structure of the heat conducting device 900 and reduce cost.

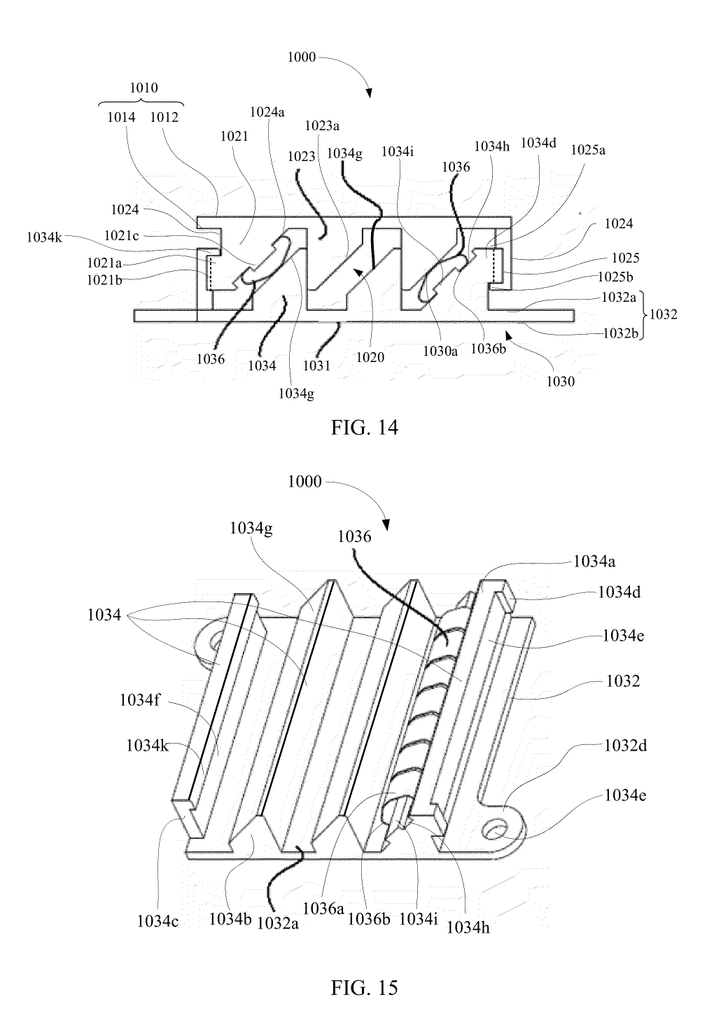

Referring to FIG. 14, FIG. 14 is a side view of a heat conducting device 1000 provided according to a tenth embodiment of this invention. The heat conducting device 1000 comprises a first heat conducting board 1010 and a heat conducting structure 1030. The first heat conducting board 1010 comprises at least one upper heat conducting arm 1020 provided on a side surface of the first heat conducting board 1010. The heat conducting structure 1030 directly faces the upper heat conducting arm 1020 of the first heat conducting board 1010 and slidably abuts against the upper heat conducting arm 1020 to perform heat transfer through the contact surface between the heat conducting structure 1030 and the upper heat conducting arms 1020. The heat conducting structure 1030 comprises a heat conducting surface 1031 and is used to keep a relative position between the first heat conducting board 1010 and the heat conducting surface. The distance between the first heat conducting board 1010 and the heat conducting surface 1031 of the heat conducting structure 1030 can be varied by means of relative sliding between the upper heat conducting arms 1020 and the heat conducting structure 1030, at the same time, it is ensured that a contact surface for heat transfer always exists between the upper heat conducting arm 1020 of the first heat conducting board 1010 and the heat conducting structure 1030.

The first heat conducting board 1010 comprises a first surface 1012 and a second surface 1014 corresponding to the first surface 1012.

This embodiment comprises multiple upper heat conducting arms 1020, containing a first upper heat conducting arm 1021, two second upper heat conducting arms 1023 and a third upper heat conducting arm 1025. The first upper heat conducting arm 1021, the second upper heat conducting arms 1023 and the third upper heat conducting arm 1025 are sequentially provided on a second surface 1014 of the first heat conducting board 1010. A first limit protrusion 1021a protruding from a side surface 1024 and flush with an end surface 1022 of the first upper heat conducting arm 1021 is provided on the side surface 1024 of the first upper heat conducting arm 1021 adjacent to an edge of the first heat conducting board 1010. The first limit protrusion 1021a is used to match with a corresponding limit structure on the heat conducting structure 1030 to restrict the position between the first heat conducting board 1010 and the heat conducting structure 1030. A first trench 1021b is provided on the first limit protrusion 1021a along a direction perpendicular to the first heat conducting board 1010, the depth of which is less than the height of the first limit protrusion 1021a with respect to the side surface 1024 where the first limit protrusion 1021a locates. The first trench 1021b is used for guiding and position limiting during the assembly of the first heat conducting board 1010 and the heat conducting structure 1030. A first slant 1024a is formed on the first upper heat conducting arm 1021 on a side surface 1024 corresponding to the side surface where the first trench 1021b is formed. A first convex bar 1021c running through the first slant 1024a along a direction parallel to the extending direction of the longer side of the end side 1022 of the first upper heat conducting arm 1021 is formed at the middle portion of the first slant 1024a of the first upper heat conducting arm 1021. The two second upper heat conducting arms 1023 are provided on the first heat conducting board 1010 on one side of the first upper heat conducting arm 1021 with an interval. A second slant 1023a parallel to the first slant 1024a is formed on each of the second upper heat conducting arms 1023. The third upper heat conducting arm 1025 is provided on the first heat conducting board 1010 on one side of the second upper heat conducting arms 1023 apart from the first upper heat conducting arm 1021. A first groove 1025a adjacent to the second surface 1014 of the first heat conducting board 1010 is provided on a side surface of the third upper conducting arm 1025 which facing the slant 1024a of the first upper heat conducting arm 1021. A second limit protrusion 1025b is formed on one end of the first groove 1025a apart from the first heat conducting board 1010. The second limit protrusion 1025b is used to match a corresponding limit structure on the heat conducting structure 1030 to keep the position between the first heat conducting board 1010 and the heat conducting structure 1030.

Referring to FIG. 15, FIG. 15 is a perspective schematic view of the heat conducting device 1030 provided in the tenth embodiment of this invention.

The heat conducting device 1030 comprises a second heat conducting board 1032, multiple lower heat conducting arms 1034 formed on the second heat conducting board 1032 and multiple resilient elements 1036.

The second heat conducting board 1032 comprises an upper surface 1032a and a lower surface 1032b corresponding to the upper surface 1032a. In this embodiment the heat conducting surface 1031 and the lower surface 1032b of the second heat conducting board 1032 are the same surface. The second heat conducting board 1032 is square in shape, two lips 1032d are formed on diagonal positions of the second heat conducting board 1032 respectively, with two through holes 1032e provided on the two lips 1032d for securing the second heat conducting board 1032 to an attachment, such as a heat source or a heat dispersing shield in an electronic device by means of fasteners passing through the through holes 1032e.

The structure and arrangement of the lower heat conducting arms 1034 are as same as that of the upper heat conducting arms 1020. The multiple lower heat conducting arms 1034 comprise a first lower heat conducting arm 1034a, two second lower heat conducting arms 1034b, and a third lower heat conducting arm 1034c. The first lower heat conducting arm 1034a, the second lower heat conducting arms 1034b, and the third lower heat conducting arm 1034c are sequentially provided on the upper surface 1032a of the second heat conducting board 1032. A third limit protrusion 1034d corresponding to and capable of clipping with the second limit protrusion 1025b on the third upper heat conducting arm 1025 protrudes from a side surface of the first lower heat conducting arm 1034a adjacent to an edge of the second heat conducting board 1032. A second trench 1034e is provided on the third limit protrusion 1034d on a side corresponding to an edge of the second heat conducting board 1032. The width of the second groove 1034e is larger than the length of the third upper heat conducting arm 1025 on the first heat conducting board 1010 to accommodate the third upper heat conducting arm 1025. A third slant 1034h is formed on another side of the first lower heat conducting arm 1034a opposite to side where the second groove 1034e locates, a second convex bar 1034i is formed on the third slant 1034h running through the third slant 1034h along the direction of a longer cross line between the first lower heat conducting arm 1034a and the second heat conducting board 1032. The two second lower heat conducting arms 1034b are provided on the second heat conducting board 1032 on one side of the first lower heat conducting arm 1034a at a certain interval, wherein a fourth slant 1034g parallel to the third slant 1034h is formed on each of the second lower heat conducting arms 1034b. The third lower heat conducting arm 1034c is provided on the second heat conducting board 1032 on one side of the second lower heat conducting arms 1034b apart from the first lower heat conducting arm 1034a. A second groove 1034f is formed on the third lower heat conducting arm 1034c corresponding to the first limit protrusion 1021a on the first upper heat conducting arm 1021, a fourth limit protrusion 1034k capable of clipping with the first limit protrusion 1021a is formed on one end of the second groove 1034f apart from the upper surface 1032a of the second heat conducting board 1032.

The resilient elements 1036 of this embodiment are clamp springs, which each of the resilient elements 1036 comprises a dome resilient portion 1036a and clip portions 1036b extending from opposite sides of the resilient portion 1036a and bent in opposite directions, there is a distance between the ends of the two clip portions 1036b. The multiple resilient elements 1036 clip on the first convex bar 1021c of the first heat conducting board 1010 and second convex bar 1034i of the adjustable heat conducting structure 1030 through their clip portions 1036b respectively.

When assembled, the first heat conducting board 1010 is disposed above the heat conducting structure 1030, making the spaces between the upper heat conducting arms 1020 correspond to the spaces between the lower heat conducting arms 1034, and the third upper heat conducting arm 1025 and the third lower heat conducting arm 1034c relatively slide along the second groove 1034e of the first lower heat conducting arm 1034a and the first trench 1021b of the first upper heat conducting arm 1021, so that the resilient elements 1036 clipped on the first convex bar 1021c and second convex bar 1034i abut against the second slants 1023a of their adjacent upper heat conducting arms 1020 and the fourth slants 1034g of the lower heat conducting arms 1034 via the resilient portion 1036a. Then, a press is applied on the first heat conducting board 1010, the resilient portions 1036a of the resilient elements 1036 produce a elastic deformation under the press, and a elastic force due to the elastic deformation of the resilient portions 1036a may cause a trend of mutual separation between the first heat conducting board 1010 and the heat conducting structure 1030 in the direction perpendicular to the first heat conducting board 1010, and a trend of mutual close in the direction parallel to the first heat conducting board 1010. As the upper heat conducting arms 1020 are inserted into the spaces between the lower heat conducting arms 1034 step by step, the first limit protrusion 1021a and the second limit protrusion 1025b of the first heat conducting board 1010 clip with the fourth limit protrusion 1034k and the third limit protrusion 1034d of the heat conducting structure 1030 under the elastic force of the resilient elements 1036 to complete the assembly of the device 1000.

The heat conducting device 1000 provided in this embodiment may keep the relative position between the first heat conducting board 1010 and the heat conducting structure 1030, and ensure that a contact surface for heat transfer always exists between the first heat conducting board 1010 and the heat conducting structure 1030 through resilient elements 1036 having a simple structure, so as to realize an adjustable distance between the first heat conducting board 1010 and the heat conducting structure 1030 and make sure good heat transfer property at the same time, further simplifying the structure of the heat conducting device 1000 and lowering cost.

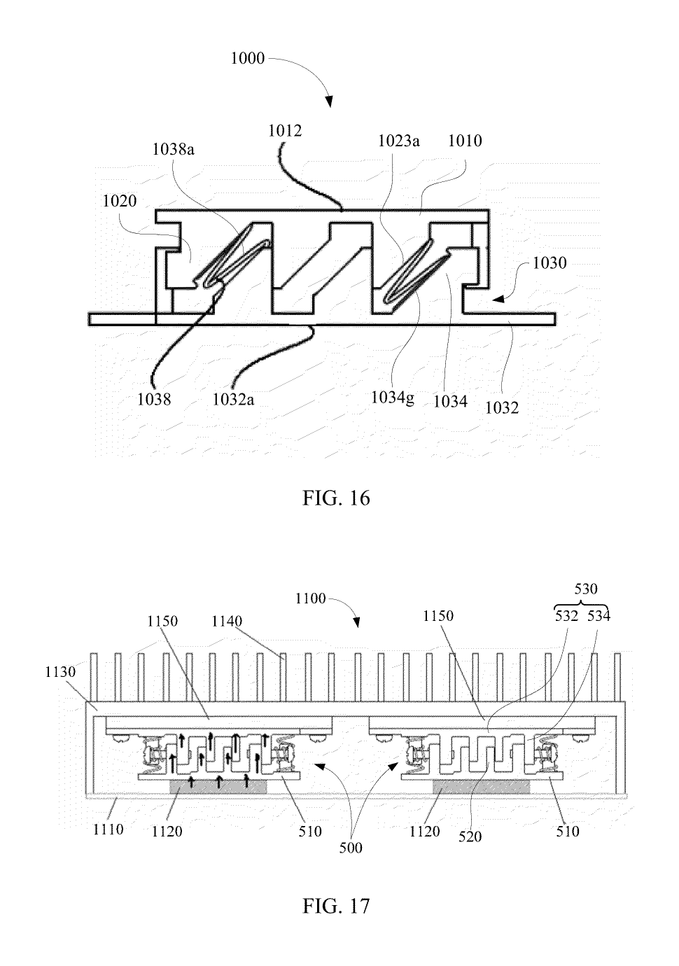

It may be understood that the structure of the resilient elements 1036 is not limited to that given in this embodiment, and may be any structure implementing the functions of the resilient elements 1036 based on the concept of this invention, in another embodiment shown in FIG. 16 for example, the resilient elements 1036 may be substituted with “Z” shaped or “V” shaped resilient elements 1038, which may abut against the second slants 1023a of their adjacent upper heat conducting arms 1020 and the fourth slants 1034g of the lower heat conducting arms 1034 with their mutually apart resilient arms 1038a to provide a elastic force capable of keeping the position relationship between the first heat conducting board 1010 and the adjustable heat conducting structure 1030, and ensuring that a contact surface for heat transfer always exists between the upper heat conducting arms 1020 and the lower heat conducting arms 1034.

All of the heat conducting devices provided in the above embodiments of this invention may be used in various electronic products for heat dispersion. In order to illustrate the arrangement of heat conducting devices of this invention in electronic products, the heat conducting device 500 provided in the fifth embodiment of this invention is merely used for illustrate its application in an electronic device.

Referring to FIG. 17, FIG. 17 is an electronic device 1100 in which a heat conducting device 500 is applied provided in the eleventh embodiment of this invention.

The electronic device comprises a circuit board 1110, multiple chips 1120 mounted on the circuit board 1110, a heat dispersing shield 1130 provided on the circuit board 1110 for accommodating the multiple chips 1120, a heat dispersion device 1140 on the heat dispersing shield 1130, one or more heat conducting devices 500 disposed between the chips 1120 and the heat dispersing shield 1130. The second heat conducting boards 532 of the heat conducting structures 530 of the heat conducting devices 500 are fixed on the inner sides of the heat dispersing shield 1130 corresponding to the chips 1120, the heat conducting surfaces 531 of the heat conducting structures 530 are closely attached to the heat dispersing shield 1130. The first heat conducting boards 510 of the heat conducting devices 500 are arranged and closely attached on the surfaces of the chips 1120. When the distances between the multiple chips 1120 and the heat dispersing shield 1130 are different, good heat transfer may be realized through independently adjusting the distances between the first heat conducting boards 510 and the heat conducting surfaces 531 with the heat conducting structures 530 of the heat conducting devices 500 to cause the heat conducting devices 500 to keep good contact between the chips 1120 and the heat dispersing shield 1130 all the time. For more sufficient contact between the heat conducting structures 530 and the heat dispersing shield 1130, and thus better heat transfer effect, heat dispersion convexes 1150 can be provided between the heat conducting structures 530 and the heat dispersing shield 1130.

Furthermore, it may be understood that in order to provide good heat conduction property for a heat conducting device provided in the above embodiment of this invention and an electronic device using the heat conducting device, a heat conducting filler or a conductive interface material can be filled between the contact surfaces for heat transfer of the heat conducting device and the electronic device using the heat conducting device.

The heat conducting device employed in the electrical device provided in the embodiment of this invention may adjust its own thickness according to use environments and manufacture errors to adapt variations in distance between a heat source and the heat dispersion structure, so as to ensure effective heat dispersion of the electronic device. Further, the heat conducting device provided in the embodiment of this invention employs high thermal conductivity materials for heat conduction, so that heat conduction efficiency can be greatly improved, at the same time, the structure of the heat conducting device provided in the embodiment of this invention is simple and easy to implement, thus, cost can be reduced and energy can be saved through large scale production.

The description above is merely preferable embodiments of this invention, but is not intended to limit this invention. Any modification, equivalent or improvement in the spirit and principle of this invention should be covered in the scope of this invention.

What is claimed is:

1. A heat conducting device, wherein,
the heat conducting device comprises a first heat conducting board and a heat conducting structure, the first heat conducting board comprising an upper heat conducting arm provided on one surface of the first heat conducting board, the heat conducting structure slidably abutting against the upper heat conducting arm of the first heat conducting board to form a contact surface through which heat transfer is realized, the heat conducting structure comprising a heat conducting surface, wherein the heat conducting structure is used to keep the relative position between the first heat conducting board and the heat conducting surface, allow the varying of the distance between the first heat conducting board and the heat conducting surface of the heat conducting structure by means of relative sliding between the upper heat conducting arm and the heat conducting structure, and ensure that a contact surface for heat transfer always exists between the upper heat conducting arm of the first heat conducting board and the heat conducting structure.

2. The heat conducting device according to claim 1, wherein,
the heat conducting structure comprises at least one lower heat conducting arm relatively slidable with respect to the upper heat conducting arm, wherein the heat conducting structure and the upper heat conducting arm of the first heat conducting board slidablly abut with each other through the lower heat conducting arm.

3. The heat conducting device according to claim 2, wherein,
the upper heat conducting arm is formed by a resilient material.

4. The heat conducting device according to claim 2, wherein,
the lower heat conducting arm is formed by a resilient material.

5. The heat conducting device according to claim 2, wherein,
the heat conducting structure further comprises a second heat conducting board, the second heat conducting board comprises an upper surface and a lower surface opposite to the upper surface, wherein the heat conducting surface is positioned on the lower surface and the lower heat conducting arm is provided on the upper surface of the second heat conducting board.

6. The heat conducting device according to claim 5, wherein,
the at least one lower heat conducting arm comprises two heat conducting reeds having the same structure and symmetrically provided on the upper surface of the second heat conducting board, each of the heat conducting reeds comprising a support portion and a resilient portion formed on an end of the support portion, wherein the resilient portions of the heat conducting reeds abut against the sides of the upper heat conducting arm.

7. The heat conducting device according to claim 2, wherein,
the at least one upper heat conducting arm comprises two structural symmetric resilient sheets, wherein each of the resilient sheets comprises a connecting segment and a abutting segment connected to the connecting segment, wherein the upper heat conducting arm abuts against the lower heat conducting arm through the abutting segments.

8. The heat conducting device according to claim 7, wherein,
the two resilient sheets of the at least one upper heat conducting arm are symmetrically provided on the first heat conducting board, such that the abutting segments of the two resilient sheets abut are located on divergent sides of the connecting segments of the resilient sheets.

9. The heat conducting device according to claim 8, wherein,
the two resilient abutting segments of the at least one upper heat conducting arm form a taper having a cross section gradually shrinking along the direction of from a position close to the first heat conducting board toward a position apart from the first heat conducting board.

10. The heat conducting device according to claim 9, wherein,
the heat conducting structure further comprises a second heat conducting board, wherein the lower heat conducting arm is provided on the second heat conducting board and forms an angle with the second heat conducting board; the lower heat conducting arm comprises two heat conducting reeds having the same structure and symmetrically provided on the second heat conducting board; the lower heat conducting arm and the abutting segments of the upper heat conducting arm abut with each other through the heat conducting reeds.

11. The heat conducting device according to claim 2, wherein,
the lower heat conducting arm comprises a locating segment, two resilient segments connected to the opposite sides of the locating segment respectively, and two resilient boom segments connected to corresponding ends of the resilient segments respectively;
the bottom of the locating segment forms the heat conducting surface, and the upper heat conducting arm abuts against the resilient boom segments of the lower heat conducting arm.

12. The heat conducting device according to claim 11, wherein,
the two resilient segments of the lower heat conducting arm are connected to the opposite sides of the locating segment, the middle portions of the two resilient segments are folded along opposite directions to form energy storage portions, the two resilient boom segments of the lower heat conducting arm are connected to one end of the resilient segments apart from the locating segment respectively by means of paralleling to the locating segment, and are opposite to each other.

13. The heat conducting device according to claim 12, wherein,
the upper heat conducting arm comprises an end surface and a side surface perpendicularly surrounding the end surface; a taper surface is formed between the end surface and the side surface of the upper heat conducting arm; the upper heat conducting arm abuts against the two resilient booms of the lower heat conducting arm through the taper surface of the upper heat conducting arm.

14. The heat conducting device according to claim 2, wherein,
two upper heat conducting arms spaced apart are provided on the first heat conducting board of the heat conducting device; the lower heat conducting arm corresponds to the spaced region between the two upper heat conducting arms of the first heat conducting board; the lower heat conducting arm comprises a locating segment, two resilient segments connected to the opposite sides of the locating segment respectively, and two resilient boom segments connected to corresponding ends of the resilient segments respectively; the bottom of the locating segment forms the heat conducting surface; the two upper heat conducting arms abut against the resilient boom segments of the lower heat conducting arm respectively.

15. The heat conducting device according to claim 14, wherein,
the two resilient segments of the lower heat conducting arm are connected to the opposite ends of the locating segment; the two resilient boom segments are connected to the sides of the resilient segments apart from the locating segment along divergent directions respectively and are folded towards the locating segment.

16. The heat conducting device according to claim 2, wherein,
the heat conducting structure further comprises a second heat conducting board and a resilient element;
the lower heat conducting arm is provided on the second heat conducting board; the heat conducting surface is formed on the second heat conducting board; the resilient element is provided on the heat conducting structure or the first heat conducting board, and abuts against the lower heat conducting arm or the upper conducting arm to keep close abutting between the lower heat conducting arm and the upper conducting arm.

17. The heat conducting device according to claim 16, wherein,
the resilient elements comprise a first resilient element and a second resilient element;
the first resilient element is provided between the first heat conducting board and the second heat conducting board to keep the distance between the heat conducting surfaces of the first heat conducting board and the second heat conducting board; the second resilient element is provided on the second heat conducting board at a position adjacent to the lower heat conducting arm and abut against the upper heat conducting arm, so that the upper heat conducting arm of the first heat conducting board closely abuts against the lower heat conducting arm of the heat conducting structure.

18. The heat conducting device according to claim 17, wherein,
the first heat conducting board comprises a first surface and a second surface opposite to the first surface;
the upper heat conducting arm is provided on the second surface of the first heat conducting board; first locating posts are further formed on the second surface of the first heat conducting board; the resilient elements for keeping the distance between the first heat conducting board and the second heat conducting board are set around the first locating posts.

19. The heat conducting device according to claim 18, wherein,
the second heat conducting board comprises an upper surface and a lower surface opposite to the upper surface; the heat conducting surface and the lower surface of the second heat conducting board are the same surface; the lower heat conducting arm is provided on the upper surface of the second heat conducting board; second locating posts are formed on the upper surface of the second heat conducting board; the second locating posts are symmetrically arranged in space with respect to the first locating posts; the resilient elements for keeping the distance between the first conducting board and the second conducting board are set around the first locating posts and the second locating posts respectively.

20. The heat conducting device according to claim 19, wherein,
multiple upper heat conducting arms are provided on the first heat conducting board of the heat conducting device; the multiple upper heat conducting arms are plate structures spaced apart and provided on the second surface of the first heat conducting board in parallel; multiple lower heat conducting arms are provided on the second heat conducting board; the lower heat conducting arms are provided on the upper surface of the second heat conducting board in the same arrangement manner as the upper heat conducting arms; the upper heat conducting arms and the lower heat conducting arms are arranged alternately and abut with each other.

21. The heat conducting device according to claim 20, wherein,
the two outmost upper heat conducting arms among the multiple upper heat conducting arms are provided with multiple first screw holes and first sliding holes corresponding to each other, wherein the multiple first screw holes are provided on a same upper heat conducting arm, and the first sliding holes are provided on the another upper heat conducting arm; the two outmost lower heat conducting arms among the multiple lower heat conducting arms are provided with second sliding holes and second screw holes corresponding to the first screw holes and first sliding holes on the upper heat conducting arms respectively; the heat conducting structure further comprises multiple locking elements; the resilient elements for keeping close abutting between the upper heat conducting arms and the lower heat conducting arms are set around the locking elements; the locking elements and the resilient elements setting around the locking elements are locked into the first screw holes and the second screw holes respectively and extended into the second sliding holes and the first sliding holes correspondingly.

22. The heat conducting device according to claim 21, wherein,
wherein the first sliding holes and the second sliding holes have a hole diameter larger than that of the first screw holes and the second screw holes, and the first sliding holes and the second sliding holes are elongate holes.

23. The heat conducting device according to claim 16, wherein,
the resilient element comprises a locating segment, a support segment connected to the locating segment and a resilient segment connected to an end of the support segment;
the resilient element is fixed on the second heat conducting board through the locating segment; the resilient segment of the resilient element abuts against the upper heat conducting arm.

24. The heat conducting device according to claim 23, wherein,
the support segment of the resilient element is perpendicularly connected to an end of the locating segment; the resilient segment is connected to an end of the support segment apart from the locating segment and inclines towards the second heat conducting board.

25. The heat conducting device according to claim 24, wherein,
a slant is formed on the upper heat conducting arm, which abuts against the resilient segment of a resilient element corresponding to the upper heat conducting arm.

26. The heat conducting device according to claim 25, wherein,
a transition surface is provided between the slant and the end surface of the upper heat conducting arm; a block protruding from the transition surface is provided at a position on the transition surface adjacent to the end surface of the upper heat conducting arm; the block and the end of the resilient segment of the resilient element abut with each other.

27. The heat conducting device according to claim 16, wherein,
limit structures capable of clipping with each other are provided on the upper heat conducting arm and the lower heat conducting arm respectively to restrict the relative position between the first heat conducting board and the heat conducting surface.

28. The heat conducting device according to claim 27, wherein,
a groove is provided on corresponding ends of the upper heat conducting arm and the lower heat conducting arm; the resilient elements are provided in the grooves of the upper heat conducting arm and the lower heat conducting arm respectively.

29. The heat conducting device according to claim 28, wherein,
the resilient element comprises a fixing portion, two first resilient arms symmetrically formed on opposite sides of the fixing portion, and a second resilient arm on the fixing portion positioned on an side edge between the two first resilient arms;
the resilient element is fixedly mounted in the groove of the upper heat conducting arm and the lower heat conducting arm through the fixing portion; the first resilient arms of the resilient element abut against the first heat conducting board or second heat conducting board corresponding to the first resilient arms; the second resilient arm of the first resilient element abuts against an adjacent upper heat conducting arm or lower heat conducting arm.

30. The heat conducting device according to claim 29, wherein,
parallel slants are provided on the upper heat conducting arm and the lower heat conducting arm respectively; the resilient element is elastically clipped between the slants of the corresponding upper heat conducting arm and the lower heat conducting arm.

31. The heat conducting device according to claim 30, wherein,
convex bars are provided on the slants of the upper heat conducting arm and the lower heat conducting arm respectively; the resilient elements are clipped on the convex bars.

32. The heat conducting device according to claim 27, wherein,
the limit structures are multiple limit protrusions mutually clipped with each other, which are provided on the upper heat conducting arm and the lower heat conducting arm respectively.

33. An electronic device applying the heat conducting device according to claim 1, wherein,
the electronic device comprises a circuit board, multiple chips provided on the circuit board, a heat dispersing shield provided on the circuit board for accommodating the chips, a heat dispersion device provided on the heat dispersing shield, and multiple heat conducting devices;
the multiple heat conducting devices are provided between the chips and the heat dispersing shield; first heat conducting boards of the heat conducting devices are closely adhered to the chips; the heat conducting structures of the heat conducting devices tightly abut on the heat dispersing shield through their heat conducting surfaces.

34. The electronic device according to claim 33, wherein,
a heat dispersion convex is provided between the heat conducting surfaces of the heat conducting structure and the heat dispersion shield.
